(19) United States
(12) Patent Application Publication
(10) Pub. No.: US 2018/0229477 A1
(43) Pub. Date: Aug. 16, 2018

(54) GLASS-RESIN COMPOSITE AND METHOD FOR PRODUCING SAME

(71) Applicant: ASAHI GLASS COMPANY, LIMITED, Chiyoda-ku (JP)

(72) Inventors: Akio Koike, Tokyo (JP); Junichi Kakuta, Tokyo (JP); Hideaki Hayashi, Tokyo (JP)

(73) Assignee: ASAHI GLASS COMPANY, LIMITED, Chiyoda-ku (JP)

(21) Appl. No.: 15/953,853

(22) Filed: Apr. 16, 2018

Related U.S. Application Data
(63) Continuation of application No. PCT/JP2016/080725, filed on Oct. 17, 2016.

(30) Foreign Application Priority Data
Oct. 20, 2015 (JP) 2015-206528

(51) Int. Cl. B32B 17/06; B32B 7/12; C03C 21/00; C03C 3/087; C03C 4/18; C09J 7/38; G03F 1/60; G03F 1/48; G03F 1/76

(52) U.S. Cl. CPC B32B 17/064; B32B 7/12; C03C 21/002; C03C 3/087; C03C 4/18; C09J 7/38; C09J 2467/00; G03F 1/48; G03F 1/76; B32B 2457/202; B32B 2307/54; C03C 2204/00; C09J 2400/143; G03F 1/60

(57) ABSTRACT

A glass-resin composite including a glass sheet and a resin film, in which: the resin film is provided all over at least one of main surfaces of the glass sheet; the glass sheet is of a chemically strengthened glass having a compressive stress layer in each of surface layers of the main surfaces and edge surfaces; the glass sheet has a sheet thickness t1 of 0.05-0.25 mm; and the sheet thickness t1, a thickness t2 of the resin film, and yield stress P of the resin film satisfy a relation of {t1 (mm)×4(N/mm²)<t2 (mm)×P(N/mm²)}.

### TECHNICAL FIELD

The present invention relates to a glass-resin composite including a glass sheet and a resin film, and a method for producing the same.

### BACKGROUND ART

A resin film such as PET applicable for a roll process has been hitherto used as a material of a photomask substrate, an LCD image mask substrate, etc. However, the resin film is so high in thermal expansion coefficient or humidity expansion coefficient as to generate a dimensional change in accordance with temperature or humidity. It is therefore difficult to apply the resin film to applications requiring higher precision.

A quartz glass or the like hardly inducing a dimensional change has been therefore used as the material of a photomask substrate, an LCD image mask substrate, etc.

Patent Document 1 discloses a method for handling a glass film, in which a thinned glass film attached to a releasable plastic film is adhered on a desired place, and the plastic film is then released and removed, so that the glass film can be prevented from being damaged easily when it is handled.

Patent Document 2 discloses a glass film laminate in which a support sheet, a glass film and a protective sheet are stacked in this order.

### BACKGROUND ART DOCUMENT

### Patent Document

Patent Document 1: JP-A-2001-97733

Patent Document 2: JP-A-2010-228166

### SUMMARY OF THE INVENTION

### Problems that the Invention is to Solve

A film mask is inserted into a device such as a plotter or an automatic developing machine when it is exposed to light or developed. Then, the film mask is automatically conveyed while being bent in a roll process. Therefore, when a glass is used as the film mask, the glass is required not to be cracked even when it is bent along a roll inside the device.

In order to satisfy flexibility high enough to be bent along the roll, a method in which the sheet thickness of the glass is reduced can be considered. However, when the sheet thickness is reduced, the mechanical strength of the glass is reduced correspondingly, and the handleability of the glass also deteriorates. In addition, when the glass sheet is broken, the glass may be scattered.

The glass film disclosed in Patent Document 1 is apt to be cracked from an edge portion of the glass film so as to be chipped or broken. Incidentally, a minute flaw remains in the edge portion, and cracking or chipping starts at the minute flaw. In a glass laminate producing method disclosed in Patent Document 1, a strengthening treatment cannot be performed on all the surface layers of edge surfaces of a glass, and the mechanical strength of the glass cannot be improved sufficiently.

A glass which substantially has no content of alkali components is used for the glass film laminate disclosed in Patent Document 2. Therefore, a chemical strengthening treatment cannot be performed. Such a glass is low in mechanical strength, and handleability thereof also deteriorates. In addition, since a protective sheet is releasably disposed on the glass film, the glass cannot be sufficiently prevented from scattering.

Therefore, an object of the present invention is to provide a glass-resin composite including a glass sheet and a resin film and having excellent flexibility and excellent mechanical strength, and a method for producing the glass-resin composite.

### Means for Solving the Problems

The present invention is as follows.

[1] A glass-resin composite including a glass sheet and a resin film, in which:

the resin film is provided all over at least one of main surfaces of the glass sheet;

the glass sheet is of a chemically strengthened glass having a compressive stress layer in each of surface layers of the main surfaces and edge surfaces;

the glass sheet has a sheet thickness t1 of 0.05-0.25 mm; and

the sheet thickness t1, a thickness t2 of the resin film, and yield stress P of the resin film satisfy a relation of {t1 (mm)×4 (N/mm²)<t2 (mm)×P(N/mm²)}.

[2] The glass-resin composite according to [1], in which a shape of each main surface of the glass sheet is an approximately rectangular shape in which a lateral length is less than 10 times of a longitudinal length.
[3] The glass-resin composite according to [1] or [2], in which a shape of the resin film is an approximately rectangular shape in which a lateral length is 10 or more times as large as a longitudinal length.
[4] The glass-resin composite according to any one of [1] to [3], in which the resin film is provided all over both of the main surfaces of the glass sheet.
[5] The glass-resin composite according to any one of [1] to [4], in which the resin film protrudes from at least a part of a contour line of the glass sheet, and a largest length of the protruding part is 10 mm or more.
[6] The glass-resin composite according to any one of [1] to [5], in which a layer containing a photosensitive material is provided on a main surface of the resin film on an opposite side to the glass sheet.
[7] The glass-resin composite according to any one of [1] to [6], in which:

the resin film is provided all over at least one of the main surface of the glass sheet through a layer containing a pressure-sensitive adhesive material; and

the layer containing the pressure-sensitive adhesive material has a 90 degree peel adhesion of 0.01 N/25 mm or more.

[8] The glass-resin composite according to any one of [1] to [7], having a total thickness of 0.3 mm or less.
[9] The glass-resin composite according to any one of [1] to [8], in which the glass sheet includes, in terms of mass % on the basis of oxides, 65-75% of SiO₂, 0.1-8.6% of Al₂O₃, 2-10% of MgO, 1-10% of CaO, 10-18% of Na₂O, 0-8% of K₂O, and 0-4% of ZrO₂, provided that Na₂O+K₂O is 10-18%.
[10] A method for producing a glass-resin composite, including, in the following order, the steps of:

chemically strengthening a glass sheet having a sheet thickness t1 of 0.05 mm to 0.25 mm; and

providing a resin film all over at least one of main surfaces of the glass sheet, the resin film having a thickness t2 and yield stress P which satisfy a relation of t1 (mm)×4 (N/mm²)<t2 (mm)×P(N/mm²).

[11] A method for producing a glass-resin composite, including, in the following order, the steps of:

chemically strengthening a glass sheet having a sheet thickness t1 of 0.05 mm to 0.25 mm;

providing a resin film all over at least one of main surfaces of the glass sheet, the resin film having a thickness t2 and yield stress P which satisfy a relation of t1 (mm)×4 (N/mm²)<t2 (mm)×P(N/mm²); and

providing a layer containing a photosensitive material on a main surface of the resin film on an opposite side to the glass sheet.

[12] The method for producing a glass-resin composite according to [10] or [11], in which, in the step of providing the resin film, the resin film is provided on the glass sheet so that the resin film protrudes from at least a part of a contour line of the glass sheet, and a largest length of the protruding part is 10 mm or more.
[13] The method for producing a glass-resin composite according to any one of [10] to [12], in which, in the step of providing the resin film, the resin film is provided all over at least one of the main surfaces of the glass sheet through a layer containing a pressure-sensitive adhesive material, and the layer containing the pressure-sensitive adhesive material has a 90 degree peel adhesion of 0.01 N/25 mm or more.
[14] The method for producing a glass-resin composite according to any one of [11] to [13], further including, after providing the layer containing the photosensitive material, a step of exposing the layer containing the photosensitive material to light.

### Advantages of the Invention

A glass sheet in a glass-resin composite according to the present invention has less dimensional change and has flexibility high enough to be bent without cracking. In addition, the glass sheet has high strength and excellent handleability. Further, since the glass sheet is combined with a resin film, the glass sheet can be prevented from scattering even if it is cracked.

Accordingly, the glass-resin composite according to the present invention can be suitably used for a precise application such as a film mask. Further, the glass-resin composite can be automatically conveyed while being bent in a roll process inside a device such as a plotter or an automatic developing machine when the glass-resin composite is exposed to light or developed.

### BRIEF DESCRIPTION OF THE DRAWINGS

FIG. 1 is a sectional view of a glass-resin composite in Example 2, in which a resin film is provided all over one main surface of a glass sheet.

FIG. 2 is a sectional view of a glass-resin composite in Example 3, in which resin films are provided all over both main surfaces of a glass sheet.

FIG. 3 is a sectional view of a glass-resin composite in Comparative Example 4, in which a resin film is provided only in edge portions on one main surface of a glass sheet.

### MODE FOR CARRYING OUT THE INVENTION

The present invention will be described in detail below. The present invention is not limited to the following embodiment, but it may be carried out with any change without departing from the gist of the invention.

In the present description, a sign “−” representing a numerical range is used as a meaning including a lower limit and an upper limit designated by numerical values stipulated before and after the sign.

### <Glass-Resin Composite>

A glass-resin composite according to an embodiment of the present invention includes a glass sheet and a resin film. The glass-resin composite is characterized in that: the resin film is provided all over at least one of main surfaces of the glass sheet; the glass sheet is of a chemically strengthened glass having a compressive stress layer in each of surface layers of the main surfaces and edge surfaces; the glass sheet has a sheet thickness t1 of 0.05-0.25 mm; and the sheet thickness t1, a thickness t2 of the resin film, and yield stress P of the resin film satisfy a relation of {t1 (mm)×4 (N/mm²)<t2 (mm)×P(N/mm²)}.

### (Glass Sheet)

It is preferable to use a glass sheet so that expansion (dimensional change) caused by humidity change can be prevented.

When the glass sheet is bent, bending stress σ is generated in accordance with a curvature radius R of the glass sheet. The curvature radius R and the bending stress σ can be expressed by the following equation.

σ=Ed/2(1−ν²)R

The signs in the aforementioned equation have the following meanings respectively.

σ: bending stress

E: Young's modulus

d: sheet thickness

ν: Poisson's ratio

R: curvature radius

For example, assume that the Young's modulus of a glass is 72 GPa, and the Poisson's ratio of the glass is 0.23. In this case, when the glass has a sheet thickness of 0.15 mm and a curvature radius of 25.2 mm, bending stress of about 230 MPa is applied to the glass. When the value of surface compressive stress (CS; Compressive Stress) of the glass sheet is not higher than the aforementioned value of the bending stress, a crack appears in the glass sheet which is being bent with the curvature radius. On the other hand, when the compressive stress value is higher than the value of the bending stress, the glass sheet can be bent with the curvature radius.

As the curvature radius is reduced, the bending stress increases. Accordingly, the glass sheet is required to have higher strength. It is preferable that the glass sheet according to the embodiment of the present invention has strength high enough not to be cracked even when the curvature radius is 25 mm or less, and it is more preferable that it has strength high enough not to be cracked even when the curvature radius is 23 mm.

Specifically, the CS of the glass sheet is preferably 250 MPa or more, more preferably 300 MPa or more, and further more preferably 400 MPa or more. It can be said that flexibility is improved as the CS is increased. On the other hand, it is preferable that the CS is 1,000 MPa or less because internal tensile stress (CT; Central Tension) can be prevented from excessively increasing. It is more preferable that the CS is 900 MPa or less.

Incidentally, when a compressive stress layer is formed in the glass surface, breaking strength can be enhanced in accordance with the CS of the compressive stress layer.

It is preferable that the compressive stress layer can be formed by chemical strengthening treatment to the glass sheet, and the aforementioned CS value can be attained. That is, the compressive stress layer is formed all over the surface layers of main surfaces and edge surfaces of the glass sheet by an ion exchange method. A glass composition in the compressive stress layer formed thereby is different from a glass composition inside the glass. Generally, more alkali metal ions with large ion radii are contained in the compressive stress layer than inside the glass. For example, when ion exchange is performed in a molten potassium nitrate salt bath, more K₂O is contained in the compressive stress layer than inside the glass.

A specific method of the chemical strengthening treatment will be described later. The CS value can be adjusted to a desired value by the salt concentration in the molten salt for the ion exchange, the strengthening time, the temperature of the molten salt, etc.

The depth of the compressive stress layer (DOL; Depth Of Layer) formed by the chemical strengthening treatment is not particularly limited. It is preferable that the DOL is 6 μm or more to prevent minute cracks from easily reaching the internal tensile stress layer. The DOL is more preferably 8 μm or more, further more preferably 10 μm or more, and particularly preferably 12 μm or more. On the other hand, it is preferable that the DOL is 25 μm or less to prevent the internal tensile stress CT from excessively increasing. The DOL is more preferably 20 μm or less.

The value of the DOL can be adjusted by the salt concentration in the molten salt for the ion exchange, the strengthening time, the temperature of the molten salt, etc.

Incidentally, the value of the CS and the value of the DOL can be measured by a surface stress meter.

In addition, it is preferable that the internal tensile stress CT of the chemically strengthened glass is 250 MPa or less to make it possible to suppress the glass from being fractured into pieces. The internal tensile stress CT is more preferably 200 MPa or less, and further more preferably 180 MPa or less. On the other hand, when the internal tensile stress CT is small, it is difficult to obtain a chemical strengthening effect. Therefore, the lower limit of the internal tensile stress CT is preferably 15 MPa or more, more preferably 30 MPa or more, and further more preferably 50 MPa or more.

The relation among the CS, the DOL and the CT can be approximately obtained by the following equation using the sheet thickness t1 of the glass sheet.

CT (MPa)=[CS (MPa)×DOL (μm)/{t1 (μm)−2×DOL (μm)}]

The flexibility of the glass sheet can be also improved by reduction of the sheet thickness of the glass sheet. That is, the glass having improved flexibility can be bent with a small curvature radius without cracking. On the other hand, as the sheet thickness of the glass is reduced, the mechanical strength thereof is reduced, and the handleability thereof deteriorates. In addition, it is difficult to provide a compressive stress layer in a surface layer of the glass in order to prevent the internal tensile stress from excessively increasing. Accordingly, the lower limit of the sheet thickness t1 of the glass sheet according to the embodiment of the present invention is 0.05 mm, more preferably 0.06 mm or more, further more preferably 0.08 mm or more, and particularly preferably 0.10 mm or more. On the contrary, when the sheet thickness of the glass sheet is too large, the flexibility of the glass is reduced. Accordingly, the upper limit of the sheet thickness t1 is 0.25 mm, more preferably 0.23 mm or less, further more preferably 0.21 mm or less, and particularly preferably 0.19 mm or less.

Incidentally, the sheet thickness t1 of the glass sheet is an average sheet thickness of a distance between one main surface of the glass sheet and the other main surface thereof, which can be measured by a micrometer.

The difference between the largest value and the smallest value in the sheet thickness of the glass sheet is preferably 0.03 mm or less and more preferably 0.02 mm or less in order to narrow a distribution of tensile stress occurring within any main surface of the glass sheet when the glass sheet is bent, to thereby prevent a region apt to be broken from occurring within the main surface.

The shape of each main surface of the glass sheet is not particularly limited, but it may be selected in accordance with the intended use of the glass-resin composite.

For example, when the glass-resin composite according to the embodiment of the present invention is used as a photomask, it is preferable that the main surface of the glass sheet has not a roll-like shape but an approximately rectangular sheet-like shape. That is, the shape of the main surface is preferably an approximately rectangular shape in which the lateral length is less than 10 times of the longitudinal length, and more preferably an approximately rectangular shape in which the lateral length is less than twice of the longitudinal length. Particularly, the shape of the main surface is further more preferably an approximately rectangular shape in which each side is 400-1,000 mm.

When the glass sheet has a sheet-like shape, the glass-resin composite can be produced using the glass sheet in which a compressive stress layer has been formed in each of the surface layers of the main surfaces and edge surfaces by the chemical strengthening treatment. On the other hand, when a glass having a roll-like shape is used, it is difficult to perform the chemical strengthening treatment on the glass due to its length. In addition, even when the chemical strengthening treatment is performed on the glass having the roll-like shape, the glass cut into a desired size after the treatment is used, and a compressive stress layer is not formed in an edge surface of the cut glass.

In some application of the glass-resin composite, the shape of the main surface of the glass sheet may be an approximately rectangular shape in which the lateral length is 10 or more times as large as the longitudinal length. In this case, it is preferable that the glass sheet has not a sheet-like shape but a roll-like shape. When the resin film also has a roll-like shape, the glass-resin composite can be formed into a roll-like shape. Thus, the glass-resin composite can be easily applied to a continuous process, and a high production efficiency can be expected.

Incidentally, the “edge surfaces” of the glass sheet in the present description designate surfaces connecting the two main surfaces opposed to each other. The “approximately rectangular shape” may include a shape which is not strictly rectangular due to an error range in a production process, and means a quadrangle in which the angle of each vertex is in a range of 90°±5°. In addition, the “approximately rectangular shape” may be a substantially approximately rectangular shape, and a corner portion of the glass sheet may be chamfered (C-chamfered or round-chamfered) in a straight line or a curved line.

The composition of the glass sheet is not particularly limited as long as the glass sheet can undergo ion exchange. For example, soda-lime glass, aluminosilicate glass, borosilicate glass, aluminoborosilicate glass, and the like can be used. Among them, soda-lime glass or soda silicate glass is preferable, and soda-lime glass is more preferable because the compressive stress layer depth (DOL) can be prevented from excessively increasing in the both main surfaces.

Examples of the composition of preferable glass include the following glass compositions.

(i) A glass having a composition which includes, in terms of mass %, 65-75% of SiO₂, 0.1-8.6% of Al₂O₃, 2-10% of MgO, 1-10% of CaO, 10-18% of Na₂O, 0-8% of K₂O, and 0-4% of ZrO₂, provided that Na₂O+K₂O is 10-18%. (ii) A glass having a composition which includes, in terms of mass %, 65-72% of SiO₂, 3.4-8.6% of Al₂O₃, 3.3-6% of MgO, 6.5-9% of CaO, 13-16% of Na₂O, 0-1% of K₂O, 0-0.2% of TiO₂, 0.005-0.15% of Fe₂O₃, and 0.02-0.4% of SO₃, provided that (Na₂O+K₂O)/Al₂O₃ is 1.8-5.0. (iii) A glass having a composition which includes, in terms of mol %, 60-75% of SiO₂, 0.8-4.5% of Al₂O₃, 10-19% of Na₂O, and 0.1-15% of CaO. (iv) A glass having a composition which includes, in terms of mol %, 65-72% of SiO₂, 0.8-4.5% of Al₂O₃, 5-13.5% of MgO, 0.8-9% of CaO, 12-17% of Na₂O, and 0-3% of K₂O, provided that RO/(RO+R₂O) is 0.410 or more and 0.52 or less (in the formula, RO designates alkali earth metal oxide, and R₂O designates alkali metal oxide).

In the following description, the content of each component will be expressed by mass %.

SiO₂ is a component which forms a skeleton of the glass. In addition, SiO₂ is a component which reduces occurrence of cracking when the glass surface is damaged (dented), or which reduces the ratio of destruction when the glass is dented after it is chemically strengthened. SiO₂ is also a component which reduces the thermal expansion coefficient of the glass. The content of SiO₂ is preferably 50% or more, more preferably 60% or more, further more preferably 65% or more, and particularly preferably 66% or more. When the content of SiO₂ is 50% or more, reduction in stability as the glass, acid resistance, weather resistance or chipping resistance can be avoided. On the other hand, the content of SiO₂ is preferably 75% or less, more preferably 73% or less, and further more preferably 70% or less. When the content of SiO₂ is 75% or less, reduction in meltability caused by increase in viscosity of the glass can be avoided.

Al₂O₃ is a component which is effective in improving the ion-exchangeability and the chipping resistance, or a component which increases the surface compressive stress. Al₂O₃ is also a component which prevents the thermal expansion coefficient from easily increasing at the glass transition point or higher. The content of Al₂O₃ is preferably 0.1% or more, more preferably 2% or more, and further more preferably 3.4% or more. The content of Al₂O₃ is preferably 12% or less, more preferably 8.6% or less, and further more preferably 6% or less. When the content of Al₂O₃ is 12% or less, the glass has excellent meltability.

MgO is a component which stabilizes the glass, and also a component which is required for keeping the thermal expansion coefficient moderate. The content of MgO is preferably 1% or more, more preferably 2% or more, further more preferably 3% or more, and particularly preferably 3.3% or more. On the other hand, the content of MgO is preferably 12% or less, more preferably 11% or less, further more preferably 10% or less, still more preferably 9% or less, especially further more preferably 8% or less, and particularly preferably 6% or less. When the content of MgO is 1% or more, the glass has excellent dissolubility at high temperature. On the other hand, when the content of MgO is 12% or less, the glass is hardly devitrified, but a sufficient ion-exchange rate can be obtained.

CaO is a component which improves the meltability of the glass, and also a component which is effective in keeping the thermal expansion coefficient moderate. The content of CaO is preferably 0.1% or more, more preferably 1% or more, further more preferably 4% or more, and particularly preferably 6.5% or more. On the other hand, the content of CaO is preferably 15% or less, more preferably 10% or less, further more preferably 9% or less, and particularly preferably 8% or less. When the content of CaO is 0.1% or more, the meltability can be improved. When the content of CaO is 15% or less, the surface compressive stress layer can be made deeper.

SrO is a component which is effective in adjusting the dissolubility at high temperature and the thermal expansion coefficient of the glass. The content of SrO is preferably 10% or less, more preferably 7% or less, further more preferably 5% or less, and particularly preferably 2% or less. When the content of SrO is 10% or less, the density of the glass can be reduced so that the weight of the glass can be reduced. When SrO is contained, the content thereof is preferably 1% or more, and more preferably 1.5% or more.

BaO is a component which is effective in adjusting the dissolubility at high temperature and the thermal expansion coefficient of the glass. The content of BaO is preferably 3% or less, more preferably 2% or less, and further more preferably 1% or less. When the content of BaO is 3% or less, the density of the glass can be reduced so that the weight of the glass can be reduced easily. In addition, the glass can be prevented from being damaged easily.

NaO₂ is a component which forms a surface compressive stress layer due to ion exchange, and improves the meltability of the glass. The content of NaO₂ is preferably 10% or more, more preferably 11% or more, further more preferably 12% or more, and particularly preferably 13% or more. On the other hand, the content of NaO₂ is preferably 19% or less, more preferably 18% or less, further more preferably 16% or less, and particularly preferably 15% or less. When the content of NaO₂ is 10% or more, a desired surface compressive stress layer can be formed by ion exchange. When the content of NaO₂ is 19% or less, it is possible to avoid reduction in weather resistance or acid resistance, or avoid occurrence of cracking due to indentation.

K₂O may be contained if necessary. The content of K₂O is preferably 0.1% or more. When the content of K₂O is 0.1% or more, it is possible to keep dissolubility at high temperature and a moderate thermal expansion coefficient of the glass. The content of K₂O is preferably 0.5% or more, and particularly preferably 1% or more. The content of K₂O is preferably 8% or less. When the content of K₂O is 8% or less, the density of the glass can be reduced so that the weight of the glass can be reduced. The content of K₂O is preferably 6% or less, more preferably 4% or less, further more preferably 3% or less, and particularly preferably 1% or less.

Fe₂O₃ is a component which improves the meltability of the glass. Since Fe₂O₃ is a component which absorbs thermic rays, Fe₂O₃ has an effect of promoting the thermal convection of molten glass to thereby improve the homogeneity of the glass, an effect of preventing increase in temperature of furnace bottom bricks of a melting furnace to thereby elongate the life of the furnace, etc. It is therefore preferable that Fe₂O₃ is contained in the composition in a melting process of the sheet glass using a large-sized furnace. The content of Fe₂O₃ is preferably 0.005% or more, more preferably 0.01% or more, further more preferably 0.03% or more, and particularly preferably 0.06% or more. On the other hand, an excessive content of Fe₂O₃ causes a problem of coloring. Therefore, the content of Fe₂O₃ is preferably 0.2% or less, more preferably 0.15% or less, further more preferably 0.12% or less, and particularly preferably 0.095% or less.

The Young's modulus and the Poisson's ratio of a glass are values peculiar to its material, depending on the composition of the glass, etc. The Young's modulus of a typical glass is 65-80 GPa. On the other hand, the Poisson's ratio of a typical glass is 0.21-0.24.

The Young's modulus and the Poisson's ratio of the glass can be measured by a well-known method such as an ultrasonic pulse method or a bending resonance method.

### (Resin Film)

In the glass-resin composite according to the embodiment of the present invention, the resin film is provided all over at least one of the main surfaces of the glass sheet, and serves as a protective layer. That is, when the glass sheet is bent, the resin film is bent together along the glass without deformation. When the glass is broken, the resin film prevents pieces of the glass from scattering to the outside of the composite. Incidentally, the deformation herein means that the resin film is torn or lengthened, and means that stress exceeding the yield stress of the resin film is applied to the resin film.

It is preferable that such resin films are provided all over both main surfaces of the glass sheet because the effect of preventing pieces of glass from scattering can be made more conspicuous when the glass is broken.

When t1 designates the sheet thickness of the glass sheet, t2 designates the thickness of the resin film, and P designates the yield stress of the resin film, a relation of {t1 (mm)×4 (N/mm²)<t2 (mm)×P(N/mm²)} is satisfied. Such a relational expression means that the yield stress of the resin film is higher than elastic stress generated when the glass sheet is bent, so that the resin film can be bent along the glass together therewith without being torn or lengthened when the glass is bent. When the relational expression is satisfied, it can be said that the resin film has yield stress high enough not to be irreversibly deformed even if tension required for bending the glass sheet having the sheet thickness t1 is applied.

When the thickness t2 of the resin film is too large, the effect of improving the dimensional accuracy due to the use of the glass sheet is reduced. When the thickness t2 is too small, the ability to prevent pieces of the glass sheet from scattering when the glass sheet is broken is reduced, or the resin film itself is deformed easily.

On the other hand, when the yield stress P of the resin film is too small, the resin film is deformed easily as soon as the glass sheet is bent.

The thickness t2 and the yield stress P of the resin film are not particularly limited as long as they satisfy the relation of {t1 (mm)×4 (N/mm²)<t2 (mm)×P(N/mm²)} The value of {t2 (mm)×P(N/mm²)} is preferably not smaller than {t1 (mm)×5 (N/mm²)}. The value of {t2 (mm)×P(N/mm²)} is more preferably not smaller than {t1 (mm)×6 (N/mm²)}. The value of {t2 (mm)×P(N/mm²)} is particularly preferably not smaller than {t1 (mm)×7 (N/mm²)}.

The thickness t2 is typically 6-250 μm. The thickness t2 is preferably 10 μm or more, and preferably 20 μm or less. On the other hand, it will typically go well if the yield stress P is 20 N/mm² or more. The yield stress P is preferably 50 N/mm² or more.

The thickness of the resin film can be measured by a digital micrometer, and the yield stress can be measured by JIS K 7127 (1999).

The shape of the resin film is not particularly limited, but it may be selected in accordance with the intended use of the glass-resin composite.

When the glass-resin composite is used as a photomask, it is preferable that the resin film has not a roll-like shape but an approximately rectangular sheet-like shape in which the lateral length is less than 10 times of the longitudinal length, in the same manner as the shape of the glass sheet.

In some application of the glass-resin composite, the shape of the resin film may be an approximately rectangular shape in which the lateral length is 10 or more times as large as the lateral length. In this case, it is preferable that the glass sheet has a roll-like shape. In addition, in this case, the glass sheet may have either a sheet-like shape or a roll-like shape. When the resin film has a roll-like shape, the glass-resin composite can be applied to a continuous process, and the resin film serves like a belt conveyor so that the production efficiency can be enhanced.

Suitable combination of the thickness of the glass sheet and the thickness and the yield stress of the resin film in this composite can make it difficult to crack the glass sheet even when the glass sheet is bent. In addition, even if the glass is broken, the glass can be prevented from rushing out from the broken resin film.

It is preferable that the resin films are provided all over both main surfaces of the glass sheet in order to enhance the effect of the resin films. Particularly when the glass is broken into pieces, the pieces of the glass can be more effectively prevented from scattering.

The resin film is not limited as long as it satisfies the aforementioned conditions. It is however preferable that the thermal expansion coefficient of the glass sheet is close to the thermal expansion coefficient of the resin film because deformation can be suppressed after application of a photosensitive material. Examples of the resin film include poly(ethylene terephthalate) (PET), polyimide (PI), epoxy (EP), polyamide (PA), poly(amide imide) (PAI), polyetheretherketone (PEEK), polybenzimidazole (PBI), poly(ethylene naphthalate) (PEN), poly(ether sulfone) (PES), cyclic polyolefin (COP), polycarbonate (PC), poly(vinyl chloride) (PVC), polyethylene (PE), polypropylene (PP), acrylic resin (PMMA), urethane resin (PU), and liquid crystal polymer (LCP). Among them, PET is preferred.

The resin film may be adhered on the glass sheet by a pressure-sensitive adhesive material, or may be adhered on the glass sheet by crimping or the like. Alternatively, the resin film may be formed by polymerization on the glass sheet.

When the resin film is provided on the glass sheet through a layer containing a pressure-sensitive adhesive material, the 90 degree peel adhesion of the layer containing the pressure-sensitive adhesive material is preferably 0.01 N/25 mm or more, and more preferably 0.1 N/25 mm or more.

The 90 degree peel adhesion can be measured by a method conforming to a 90 degree peel adhesion test of JIS Z 0237 (2009).

Examples of the pressure-sensitive adhesive material include acrylic resin, urethane resin, silicone resin, phenolic resin, epoxy resin, melamine resin, urea resin, unsaturated polyester resin, alkyd resin, polyimide resin, and fluororesin. Among them, acrylic resin or silicone resin excellent in thermal resistance or transparency is preferred.

When the layer containing the pressure-sensitive adhesive material is too thick, the possibility that the resin film can move freely is increased to reduce the effect of the glass sheet improving the dimensional accuracy. Therefore, the thickness of the layer containing the pressure-sensitive adhesive material is preferably 50 μm or less, and more preferably 25 μm or less.

A method for stacking the glass sheet and the resin film on each other is not particularly limited, but various methods can be used.

For example, a method in which the glass sheet is put on a surface of the resin film under a normal pressure environment may be used. It is preferable that the glass sheet is crimped on the resin film by use of a roll or a press if necessary after the glass sheet is put on the surface of the resin film. Due to the crimping by the roll or the press, bubbles entangled between the resin film and the glass sheet can be removed easily.

Crimping by a vacuum lamination method or a vacuum press method is more preferably because entangled bubbles can be suppressed or good adhesion can be secured. The crimping under a vacuum has another advantage that even when minute bubbles remain, the bubbles do not grow by heating, so that the bubbles cannot easily lead to a distortion defect of the glass sheet. In addition, due to the crimping by heating under a vacuum, bubbles hardly remain.

When the resin film and the glass sheet are stacked on each other, it is preferable that the surface of the glass sheet to be brought into contact with the resin film is washed sufficiently, and the resin film and the glass sheet are stacked on each other in an environment of Class 1-7 as to degree of cleanness conforming to JIS B 9920 (2002). As a result, the number of particles of 0.1 μm or more per 1 m³ can be reduced, and the flatness of the glass-resin composite can be improved.

It will go well only if the resin film covers the whole of the main surface of the glass sheet. The resin film may protrude from a part or all of the contour line of the glass sheet. When the glass-resin composite is used as a photomask, it is preferable that the resin film protrudes from at least a part of the contour line of the glass sheet, and the largest length of the protruding part is 10 mm or more. In this case, when the glass-resin composite is inserted into a device such as a plotter or an automatic developing machine when it is exposed to light or developed, the protruding part is wound around a roll inside the device so as to serve as a guide film by which the glass-resin composite can be guided into the device.

It is more preferable that the largest length of the protruding part has a protruding width of 15 mm or more because the protruding part can be easily engaged into the device as a guide film. The width is further more preferably 30 mm or more, and particularly preferably 50 mm or more.

In addition, it is more preferable that the resin film protrudes from all of the contour line of the glass sheet, in order to prevent pieces of the glass from scattering when the glass is broken.

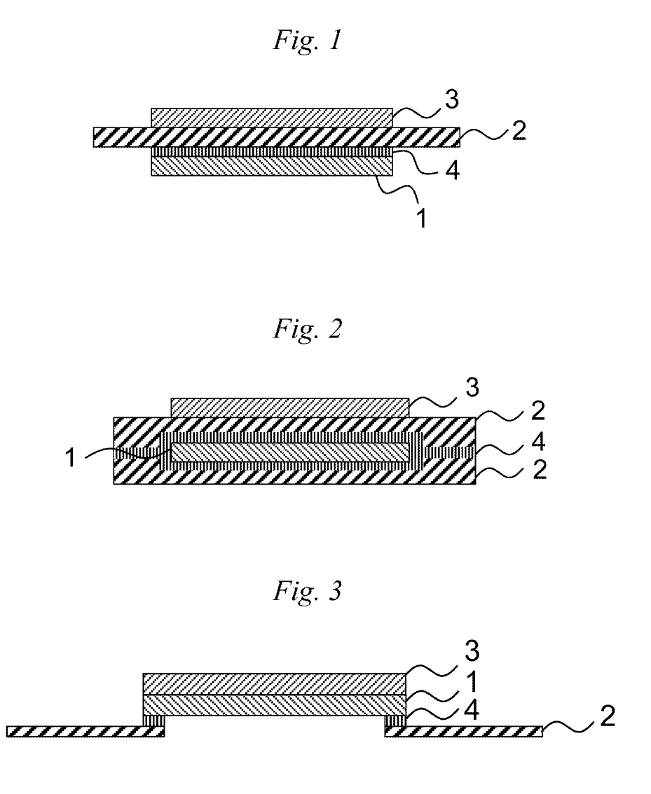

FIG. 1 shows a schematic view (sectional view) in which a resin film is provided all over one of main surfaces of a glass sheet through a layer containing a pressure-sensitive adhesive material. FIG. 2 shows a schematic view (sectional view) in which resin films are provided all over both main surfaces of a glass sheet through layers each containing a pressure-sensitive adhesive material. In FIG. 1 and FIG. 2, each part protruding outside the width of the glass sheet serves as a guide film.

### (Photosensitive Material)

When the glass-resin composite according to the embodiment of the present invention is used as a photomask or the like, it is preferable that a layer containing a photosensitive material is provided on the main surface of the resin film on the opposite side to the glass sheet. It is preferable that the photosensitive material covers the whole surface of the glass sheet located through the resin film.

A silver salt emulsion may be contained as the photosensitive material. The silver salt emulsion designates an emulsion in which microcrystals of silver halide are dispersed in a colloidal substance of gelatin and high-molecular synthetic polymer. Other than the layer containing the photosensitive material, a protective layer for preventing scratching may be provided on the main surface, and an underlayer for improving adhesion to a base material may be provided in an interface between the emulsion and the base material. When the resin film is also provided on the main surface of the glass sheet on the opposite side to the main surface where the layer containing the photosensitive material is provided, a halation preventing layer may be provided on a surface of the layer containing the photosensitive material.

It will go well if the thickness of the layer containing the photosensitive material is 1-20 μm. The thickness thereof is preferably 3 μm or more, and preferably 10 μm or less.

### (Glass-Resin Composite)

The total thickness of the glass-resin composite depends on the glass sheet, the resin film, etc. used therefor. In order to improve the flexibility, the total thickness is preferably 0.4 mm or less, more preferably 0.3 mm or less, further more preferably 0.25 mm or less, and particularly preferably 0.2 mm or less. On the other hand, in terms of the rigidity of the composite, the total thickness is preferably 0.1 mm or more, more preferably 0.12 mm or more, and particularly preferably 0.15 mm or more.

The use of the glass-resin composite according to the embodiment of the present invention is not particularly limited. For example, the glass-resin composite according to the embodiment of the present invention is suitably applied to a substrate such as a photomask. In particular, it is preferable that the glass-resin composite according to the embodiment of the present invention is used as a substitute for a film photomask for producing a substrate of a printed circuit board (PCB), so that the glass-resin composite is exposed to light to draw an image therein at a high speed by a plotter, and the image is then developed, fixed and washed by an automatic developing machine. It is more preferable that the glass-resin composite according to the embodiment of the present invention is used as an encoder film for controlling the amount of movement in an inkjet printer or the like. The glass-resin composite according to the embodiment of the present invention may be used as a display cover glass for a portable terminal, an in-vehicle display, or the like. According to the present invention, due to the suitable sheet thickness of the glass, and the suitable thickness and the suitable yield stress of the resin film, pieces of the glass can be prevented from scattering even when the glass is cracked.

### <Method for Producing Glass-Resin Composite>

A method for producing a glass-resin composite according to an embodiment of the present invention is characterized by including the following steps in this order: (i) a step of chemically strengthening a glass sheet having a sheet thickness t1 of 0.05 mm to 0.25 mm; and (ii) a step of providing a resin film all over at least one of main surfaces of the glass sheet, the resin film having a thickness t2 and yield stress P which satisfy a relation of t1 (mm)×4 (N/mm²)<t2 (mm)×P(N/mm²). Preferably a method for producing a glass-resin composite according to another embodiment of the present invention is characterized by including the following steps in this order: (i) a step of chemically strengthening a glass sheet having a sheet thickness t1 of 0.05 mm to 0.25 mm; (ii) providing a resin film all over at least one of main surfaces of the glass sheet, the resin film having a thickness t2 and yield stress P which satisfy a relation of t1 (mm)×4 (N/mm²)<t2 (mm)×P(N/mm²); and (iii) a step of providing a layer containing a photosensitive material on a main surface of the resin film on an opposite side to the glass sheet.

### (Step i: Chemically Strengthening Step)

In the chemically strengthening step, after a produced glass is cut into a glass sheet having a desired size with a sheet thickness t1 of 0.05 mm to 0.25 mm, a chemical strengthening treatment is performed on the glass sheet. The preferred form of the glass has been described in the previous section “(Glass Sheet)”. Before the chemical strengthening treatment, shaping processing may be performed in accordance with the intended use. Examples of the shaping processing include mechanical processing such as cutting, edge surface processing and perforating, and polishing processing such as chamfering.

Chemical strengthening is to replace ions near the surface of the glass sheet with ions having a large ionic radius. As a result, a compressive stress layer is formed in the surface of the glass sheet to thereby improve the strength of the glass.

Specifically, a compressive stress layer is formed by replacing Li ions in the surface of the glass sheet with Na ions and/or K ions, or replacing Na ions in the surface of the glass sheet with K ions.

When Na ions are replaced with K ions, the glass sheet containing sodium is, for example, brought into contact with inorganic molten salt containing potassium nitrate. Preferably the inorganic molten salt contains at least one kind of salt selected from the group consisting of K₂CO₃, Na₂CO₃, KHCO₃, NaHCO₃, KOH and NaOH. After that, a step of washing the glass sheet, a step of treating the glass sheet with acid and/or alkali, a step of drying the glass sheet, etc. may be included.

The CS and the DOL of the chemically strengthened glass can be adjusted by adjustment of the ion concentration in the molten salt used for the ion exchange, the strengthening time, the temperature of the molten salt, etc. For example, in the case where Na ions are replaced with K ions, higher CS can be obtained when the Na concentration in the molten salt of potassium nitrate is reduced. Deeper DOL can be obtained when the temperature of the molten salt is increased.

### (Step ii: Step of Providing Resin Film)

A resin film in which a thickness t2 and a yield stress P thereof satisfy a relation of t1 (mm)×4 (N/mm²)<t2 (mm)×P(N/mm²) is provided all over at least one of the main surfaces of the chemically strengthened glass sheet obtained in Step i.

The method for providing the resin film on the glass sheet or the preferred mode thereof has been described in the previous section “(Resin Film)”. In particular, it is preferable that the resin film is provided all over at least one of the main surfaces of the glass sheet through a layer containing a pressure-sensitive adhesive material having a 90 degree peel adhesion of 0.01 N/25 mm or more. In addition, it is preferable that the resin film is provided on the glass sheet so that the resin film protrudes from at least a part of the contour line of the glass sheet, and the largest length of the protruding part is 30 mm or more.

### (Step iii: Step of Providing Layer Containing Photosensitive Material)

When the glass-resin composite according to the embodiment of the present invention is used as a photomask, a layer containing a photosensitive layer is provided on, of the resin film provided in Step ii, the surface on the opposite side to the glass sheet. The kind of the photosensitive material or the preferred mode thereof has been described in the previous section “(Photosensitive Material)”.

The photosensitive material does not have to be applied directly to the film, but may be applied onto a buffer layer or another functional film. In addition, after the photosensitive material is applied, an overcoat may be provided further on the photosensitive material.

In order to use an existing film photomask production step, a film coated with the photosensitive material may be adhered on the glass so as to provide the layer containing the photosensitive material.

### (Step iv: Step of Exposure to Light)

For use as a photomask, it is preferable that a step of exposure to light with a pattern is provided next to Step iii. The conditions of the exposure to light are not particularly limited. Conditions which have been generally used in the background art may be used. It is preferable that the exposure with a pattern is performed using a laser beam, and it is preferable that the glass-resin composite which has been bent is exposed to light by use of a laser plotter.

### (Step v: Step of Developing and Fixing)

For use as a photomask, developing and fixing next to Step iv are performed on the glass-resin composite to form it into a photomask. After the exposure to light with a pattern, it is preferable that the glass-resin composite is immersed into a developer to be developed, immersed into a fixer to be fixed, and washed with water to thereby obtain the photomask. Preferably in the step of developing and fixing, the glass-resin composite which has been bent is brought into contact with the developer and the fixer. It is more preferable that developing and fixing are performed by an automatic developing machine.

The step of producing the glass is provided before the aforementioned Step i. The production step is not particularly limited. The glass can be produced as follows. A glass raw material adjusted to have a desired glass composition is preferably heated and melted at 1,500-1,650° C., and clarified. The molten glass is then supplied to a shaping apparatus, and shaped into a sheet-like shape. The shaped glass is cooled gradually.

Various processes can be used for shaping the glass. For example, various shaping processes including a down draw process (such as an overflow down draw process, a slot down process, a redraw process, etc.), a float process, a roll-out process, a press process, etc can be used.

Treatments such as a thermal treatment, a surface treatment, polishing, etching, etc. may be performed on the glass before or after the aforementioned steps or among the aforementioned steps. In order to reduce the sheet thickness, it is preferable that the glass sheet is thinned by chemical etching. It is preferable that the etching is performed with a chemical solution containing HF. It is more preferable that etching is performed not only on the main surfaces but also on the edge surfaces. The etching removal amount of each main surface is preferably 0.01 mm or more, more preferably 0.05 mm or more, and particularly preferably 0.1 mm or more. As a result, the strength can be improved. The etching removal amount of the main surface is preferably 0.3 mm or less, and more preferably 0.2 mm or less. As a result, the difference between the largest value and the smallest value of the sheet thickness can be reduced.

### EXAMPLES

Examples will be shown below to describe the present invention specifically. However, the present invention is not limited to the examples.

### <Example 1> (Production of Chemically Strengthened Glass Sheet)

A glass raw material which had been generally used was selected to form a soda-lime glass having a composition including, in terms of mol % on the basis of oxides, 68.8% of SiO₂, 3.0% of Al₂O₃, 6.2% of MgO, 14.2% of Na₂O, 0.2% of K₂O, and 7.8% of CaO (a composition including, in terms of mass %, 68.5% of SiO₂, 5.0% of Al₂O₃, 4.1% of MgO, 12.8% of Na₂O, 0.3% of K₂O, and 7.2% of CaO), and a glass sheet was produced therefrom by a float process using a float furnace. The obtained glass sheet was cut and polished to obtain a glass sheet which had a rectangular shape measuring 30 mm by 30 mm and having a sheet thickness of 0.15 mm. The sheet thickness of the glass sheet was measured by a digital micrometer.

The composition of the obtained glass sheet was identified by X-ray fluorescence method, and it was confirmed that it was a desired composition.

Next, the glass sheet was immersed into a molten potassium nitrate salt with a Na concentration of 0.5% and at a temperature of 430° C. for 5 hours. Thus, a chemical strengthening treatment was performed on the glass sheet. After that, the glass sheet was naturally cooled down to room temperature, and the glass sheet was washed and dried. The CS and the DOL of the chemically strengthened glass sheet obtained were measured by a surface stress meter (FSM-6000, manufactured by Orihara Industrial Co., Ltd.). The CS was 600 MPa, and the DOL was 14 μm.

### (Production of Glass-Resin Composite)

One main surface of the chemically strengthened glass sheet obtained above was disposed at the center on a resin film measuring 20 cm by 5 cm. On this occasion, the glass sheet was disposed obliquely so that a diagonal line of the glass sheet was parallel to the longitudinal direction of the resin film. A poly(ethylene terephthalate) film with a pressure-sensitive adhesive material (TG-1100, manufactured by Sumiron Co., Ltd.) was used as the resin film. The glass sheet was adhered on the resin film so that the pressure-sensitive adhesive material could contact against the glass sheet.

In the glass-resin composite obtained above, the thickness of the resin film was 25 μm, the thickness of the layer containing the pressure-sensitive adhesive material was 3 μm, and the total thickness of the glass-resin composite was 0.178 mm. The values of {glass sheet thickness t1 (mm)×4 (N/mm²)} and {resin film thickness t2 (mm)×yield stress P(N/mm²)} are shown in Table 1.

### Comparative Example 1

A glass-resin composite was produced in the same manner as in Example 1, except that the sheet thickness of the glass sheet was set at 0.3 mm.

### Comparative Example 2

A glass-resin composite was produced in the same manner as in Example 1, except that a poly(ethylene terephthalate) film with a pressure-sensitive adhesive material (Prosave 6CBF2, manufactured by Kimoto Co., Ltd.) was used, the thickness of the resin film was set at 6 μm, and the thickness of the layer containing the pressure-sensitive adhesive material was set at 4 μm.

### Comparative Example 3

A glass-resin composite was produced in the same manner as in Example 1, except that a polyethylene film (EC625, manufactured by Sumiron Co., Ltd.) having a thickness of 0.050 mm was used as the resin film, and the thickness of the layer containing the pressure-sensitive adhesive material was set at 10 μm.

Physical properties of Comparative Examples 1 to 3 are shown in Table 1.

### <Bending Test>

Of each glass-resin composite obtained in Example 1 and Comparative Examples 1 to 3, a resin film part was pulled by a universal testing machine (AG-20 kN, manufactured by Shimadzu Corporation) so that the glass-resin composite was extended along a column having a radius of 15 mm. Thus, evaluation was performed as to flexibility of the glass sheet (R=15 mm following performance) and existence (film yield stress) of deformation (tearing or elongation) of the resin film.

The reason why the glass sheet was disposed so that the diagonal line of the glass sheet was parallel to the longitudinal direction of the resin film was to concentrate stress on corner portions of the glass sheet. Thus, the test was performed as an emphasized test for the evaluation as to the flexibility of the glass and the existence of deformation of the resin film.

Results of the bending test are shown in Table 1.

The glass-resin composite in Example 1 could be bent along the column having a radius of 15 mm, and the resin film was not deformed. Therefore, both the “R=15 mm following performance” and the “film deformation” in Table 1 were evaluated as “∘”.

In the glass-resin composite in Comparative Example 1, the glass sheet was so thick that the resistance was too strong. Thus, the glass-resin composite could not be bent. Therefore, the “R=15 mm following performance” in Table 1 was evaluated as “x”. The “film deformation” was evaluated as “−”. Since the glass sheet was not bent, tearing or elongation of the resin film could not be examined.

In each of the glass-resin composites in Comparative Examples 2 and 3, when the glass sheet was being bent along the column having a radius of 15 mm, the resin film was torn before the glass was bent.

TABLE 1

| | | Comparative | Comparative | Comparative |
|---|---|---|---|---|
| | Example 1 | Example 1 | Example 2 | Example 3 |
| Glass sheet | 0.15 | 0.30 | 0.15 | 0.15 |
| thickness t1 | | | | |
| (mm) | | | | |
| Resin film | 0.025 | 0.025 | 0.006 | 0.050 |
| thickness t2 | | | | |
| (mm) | | | | |
| Resin film yield | 100 | 100 | 100 | 8 |
| stress P | | | | |
| (N/mm²) | | | | |
| t1 × 4 (N/mm) | 0.6 | 1.2 | 0.6 | 0.6 |
| t2 × P (N/mm) | 2.5 | 2.5 | 0.6 | 0.4 |
| R = 15 mm | ◯ | X | — | — |
| following | | | | |
| performance | | | | |
| Film deformation | ◯ | — | X (torn) | X (torn) |

### Example 2

A glass-resin composite is obtained in the same manner as in Example 1, except that a surface of a chemically strengthened glass is scratched by a sand-paper having a grain size of 400 (WTCC-S, manufactured by Nihon Kenshi Co., Ltd.) to thereby reduce the strength, and when one surface of the chemically strengthened glass sheet is disposed on the resin film, two opposite sides of the glass sheet are disposed to be parallel to the longitudinal direction of the resin film (the other two opposite sides of the glass sheet are disposed to be perpendicular to the longitudinal direction of the resin film). Next, a silver salt emulsion as the photosensitive material is applied to be 5 μm thick onto the main surface of the resin film on the opposite side to the glass sheet.

A sectional view of the obtained glass-resin composite is shown in FIG. 1. The thickness of the resin film of the glass-resin composite is 25 μm, the thickness of the layer containing the pressure-sensitive adhesive material is 3 μm, and the total thickness of the glass-resin composite is 0.183 mm.

### Example 3

A glass-resin composite is obtained in the same manner as in Example 2, except that a resin film is also adhered all over the opposite main surface of the chemically strengthened glass sheet through a layer containing a pressure-sensitive adhesive material in the same manner as in Example 2. Incidentally, the photosensitive material is applied onto only one of the resin films.

A sectional view of the obtained glass-resin composite is shown in FIG. 2. The thickness of each resin film of the glass-resin composite is 25 μm, the thickness of each layer containing the pressure-sensitive adhesive material is 10 μm, and the total thickness of the glass-resin composite is 0.225 mm.

### Comparative Example 4

Only on a part of 10 mm from each of a pair of edge portions on one main surface of the chemically strengthened glass sheet obtained in Example 2, a resin film is adhered through a layer containing a pressure-sensitive adhesive material. A photosensitive material is applied onto the other main surface of the chemically strengthened glass sheet in the same manner as in Example 2.

A sectional view of a glass-resin composite obtained thus is shown in FIG. 3. The thickness of the resin film of the glass-resin composite is 25 μm, and the thickness of the layer containing the pressure-sensitive adhesive material is 10 μm.

### <Scattering Preventing Test>

Each of the glass-resin composites in Examples 2 and 3 and Comparative Example 4 is subjected to a roll process using a roll having a radius of 25 mm to thereby break the glass sheet. The quantity of glass scattering without staying in the glass-resin composite is determined from the amount of reduction between weight before the test and weight after the test.

Incidentally, the surface of the chemically strengthened glass sheet is scratched to reduce the glass strength. Thus, the glass is broken easily with less power than actually.

Results are shown in Table 2.

TABLE 2

| | | | Comparative |
|---|---|---|---|
| | Example 2 | Example 3 | Example 4 |
| Glass sheet thickness | 0.15 | 0.15 | 0.15 |
| t1 (mm) | | | |
| Resin film thickness | 0.025 | 0.025 | 0.025 |
| t2 (mm) | | | |
| Resin film yield stress | 100 | 100 | 100 |
| P (N/mm²) | | | |
| State of resin film | all over one | all over both | only edge |
| | main surface | main surfaces | portions of one |
| | | | main surface |
| Reduction between | 15% | 0 (no | 87% |
| weight before breaking | | reduction) | |
| test and weight after | | | |
| breaking test | | | |

From the results of Table 1 and Table 2, it is understood that the sheet thickness t1 of the glass sheet has a preferred upper limit in order to secure good flexibility in the glass sheet. It is also understood that if the relation of {glass sheet thickness t1 (mm)×4 (N/mm²)}<{resin film thickness t2 (mm)×yield stress P(N/mm²)} is satisfied, the yield stress of the resin film can exceed the elastic force of the glass sheet when the glass is bent, so that the resin film can be bent along the glass sheet together therewith without being deformed (torn or elongated). Further, when the whole of at least one main surface of the glass sheet is covered with the resin film, the effect of preventing pieces of glass from scattering when the glass is broken can be obtained. The effect is more effective when the both main surfaces of the glass sheet are entirely covered with the resin films.

Although the present invention has been described in detail and with reference to its specific embodiments, it is obvious for those skilled in the art that various changes or modification can be made on the present invention without departing from the spirit and scope thereof. The present application is based on a Japanese patent application (Japanese Patent Application No. 2015-206528) filed on Oct. 20, 2015, the contents of which are incorporated herein by reference.

### INDUSTRIAL APPLICABILITY

Since a glass-resin composite according to the present invention has a small humidity expansion coefficient, the glass-resin composite can be also used suitably for a precise application such as a film mask. In addition, the glass-resin composite has properties such as flexibility of the glass sheet and yield stress of the resin film. Accordingly, even if the glass-resin composite is inserted into a device such as a plotter or an automatic developing machine in which the glass-resin composite is automatically conveyed in a roll process, the glass-resin composite can be integrally bent along the outer circumference of a roll inside the device without deforming the resin film. Further, even when the glass is broken into pieces, the pieces of the glass can be prevented from scattering into the device.

### DESCRIPTION OF REFERENCE NUMERALS AND SIGNS

1 glass sheet
2 resin film
3 emulsion (photosensitive material)
4 pressure-sensitive adhesive material

1. A glass-resin composite comprising a glass sheet and a resin film, wherein:
the resin film is provided all over at least one of main surfaces of the glass sheet;
the glass sheet is of a chemically strengthened glass having a compressive stress layer in each of surface layers of the main surfaces and edge surfaces;
the glass sheet has a sheet thickness t1 of 0.05-0.25 mm; and
the sheet thickness t1, a thickness t2 of the resin film, and yield stress P of the resin film satisfy a relation of {t1 (mm)×4 (N/mm²)<t2 (mm)×P(N/mm²)}.

2. The glass-resin composite according to claim 1, wherein a shape of each main surface of the glass sheet is an approximately rectangular shape in which a lateral length is less than 10 times of a longitudinal length.

3. The glass-resin composite according to claim 1, wherein a shape of the resin film is an approximately rectangular shape in which a lateral length is 10 or more times as large as a longitudinal length.

4. The glass-resin composite according to claim 1, wherein the resin film is provided all over both of the main surfaces of the glass sheet.

5. The glass-resin composite according to claim 1, wherein the resin film protrudes from at least a part of a contour line of the glass sheet, and a largest length of the protruding part is 10 mm or more.

6. The glass-resin composite according to claim 1, wherein a layer containing a photosensitive material is provided on a main surface of the resin film on an opposite side to the glass sheet.

7. The glass-resin composite according to claim 1, wherein:
the resin film is provided all over at least one of the main surface of the glass sheet through a layer containing a pressure-sensitive adhesive material; and
the layer containing the pressure-sensitive adhesive material has a 90 degree peel adhesion of 0.01 N/25 mm or more.

8. The glass-resin composite according to claim 1, having a total thickness of 0.3 mm or less.

9. The glass-resin composite according to claim 1, wherein the glass sheet comprises, in terms of mass % on the basis of oxides, 65-75% of SiO₂, 0.1-8.6% of Al₂O₃, 2-10% of MgO, 1-10% of CaO, 10-18% of Na₂O, 0-8% of K₂O, and 0-4% of ZrO₂, provided that Na₂O+K₂O is 10-18%.

10. A method for producing a glass-resin composite, comprising, in the following order, the steps of:
chemically strengthening a glass sheet having a sheet thickness t1 of 0.05 mm to 0.25 mm; and
providing a resin film all over at least one of main surfaces of the glass sheet, the resin film having a thickness t2 and yield stress P which satisfy a relation of t1 (mm)×4 (N/mm²)<t2 (mm)×P(N/mm²).

11. A method for producing a glass-resin composite, comprising, in the following order, the steps of:
chemically strengthening a glass sheet having a sheet thickness t1 of 0.05 mm to 0.25 mm;
providing a resin film all over at least one of main surfaces of the glass sheet, the resin film having a thickness t2 and yield stress P which satisfy a relation of t1 (mm)×4 (N/mm²)<t2 (mm)×P(N/mm²); and
providing a layer containing a photosensitive material on a main surface of the resin film on an opposite side to the glass sheet.

12. The method for producing a glass-resin composite according to claim 10, wherein, in the step of providing the resin film, the resin film is provided on the glass sheet so that the resin film protrudes from at least a part of a contour line of the glass sheet, and a largest length of the protruding part is 10 mm or more.

13. The method for producing a glass-resin composite according to claim 11, wherein, in the step of providing the resin film, the resin film is provided on the glass sheet so that the resin film protrudes from at least a part of a contour line of the glass sheet, and a largest length of the protruding part is 10 mm or more.

14. The method for producing a glass-resin composite according to claim 10, wherein, in the step of providing the resin film, the resin film is provided all over at least one of the main surfaces of the glass sheet through a layer containing a pressure-sensitive adhesive material, and the layer containing the pressure-sensitive adhesive material has a 90 degree peel adhesion of 0.01 N/25 mm or more.

15. The method for producing a glass-resin composite according to claim 11, wherein, in the step of providing the resin film, the resin film is provided all over at least one of the main surfaces of the glass sheet through a layer containing a pressure-sensitive adhesive material, and the layer containing the pressure-sensitive adhesive material has a 90 degree peel adhesion of 0.01 N/25 mm or more.

16. The method for producing a glass-resin composite according to claim 11, further comprising, after providing the layer containing the photosensitive material, a step of exposing the layer containing the photosensitive material to light.
